(19) United States
(12) Patent Application Publication
(10) Pub. No.: US 2009/0224843 A1
(43) Pub. Date: Sep. 10, 2009

(54) Programmable Crystal Oscillator

(75) Inventors: Liviu-Mihai Radoias, Ploiesti Prahova (RO); Radu H. Iacob, Santa Clara, CA (US); Iulian Dumitru, Bucuresti (RO)

Correspondence Address: BEVER HOFFMAN & HARMS, LLP;901 Campisi Way, Suite 370, Campbell, CA, 95008, US

(73) Assignee: Catalyst Semiconductor, Inc., Santa Clara, CA (US)

(21) Appl. No.: 12/045,224

(22) Filed: Mar. 10, 2008

(51) Int. Cl. H03B 5/32

(52) U.S. Cl. 331/158

(57) ABSTRACT

A crystal oscillator circuit having a parallel resonant frequency that is adjustable by switching trim capacitors in parallel with a crystal.

### FIELD OF THE INVENTION

The present invention relates to integrated circuits using standard CMOS technology. More specifically, the present invention relates to a CMOS circuit for adjusting the frequency oscillation of a crystal oscillator.

### RELATED ART

FIG. 1 is a conventional crystal oscillator circuit 100, which includes inverting amplifier 101, resistor 102 (which has a resistance RF), crystal 103, fixed load capacitors 110 and 120, a first set of programmable load capacitors 111-114, a corresponding first set of switches 131-134, a second set of programmable load capacitors 121-124, and a corresponding second set of switches 141-144.

Inverting amplifier 101, resistor 102 and crystal 103 are connected in parallel between terminals 151 and 152. Fixed load capacitors 110 and 120 are connected between terminals 151 and 152, respectively, and ground. The programmable load capacitors 111-114 can be selectively connected between terminal 151 and ground by activating switches 131-134, respectively. Similarly, the programmable load capacitors 121-124 can be selectively connected between terminal 152 and ground by activating switches 141-144, respectively. Switches 131, 132, 133 and 134 are controlled by control signals A1, A2, A3 and A4, respectively. Switches 141, 142, 143 and 144 are controlled by control signals B1, B2, B3 and B4, respectively.

The fixed load capacitors 110 and 120 have capacitances C₁₀ and C₂₀, respectively, wherein C₁₀ is typically equal to C₂₀. The programmable load capacitors 111, 112, 113 and 114 have capacitances of C₁₁, C₁₂, C₁₃ and C₁₄, respectively, and programmable load capacitors 121, 122, 123 and 124 have capacitances of C₂₁, C₂₂, C₂₃ and C₂₄, respectively. Capacitances C₁₁, C₁₂, C₁₃ and C₁₄ are typically equal to capacitances C₂₁, C₂₂, C₂₃ and C₂₄, respectively.

Crystal 103 can be modeled by an inductor 104 having an inductance L_{M}, a capacitor 105 having a capacitance C_{M}, a resistor 106 having a resistance R_{S}, and a capacitor 107 having a capacitance C₀. Inductor 104, capacitor 105 and resistor 106 are connected in series between terminals 151 and 152. Capacitor 107 is connected between terminals 151 and 152, in parallel with the series-connected inductor 104, capacitor 105 and resistor 106.

The series resonant frequency (fs) of crystal 103 is determined by the inductance L_{M} of inductor 104 and the capacitance C_{M} of capacitor 105. The series resonant frequency (fs) of crystal 103 is specified by the following equation.

$$fs = \frac{1}{2 * π * \sqrt{( {C}_{M} * {L}_{M} )}} \qquad equation ( 1 )$$

The parallel resonant frequency of oscillation (fp) of crystal oscillator circuit 100 can be represented by the following equation, wherein C_{L} is the capacitance introduced by load capacitors 110-114 and 120-124.

$$fp = fs * [ 1 + \frac{{C}_{M}}{2 * ( {C}_{0} + {C}_{L} )} ] \qquad equation ( 2 )$$

If only fixed load capacitors 110 and 120 are connected to terminals 151 and 152 (i.e., switches 131-134 and 141-144 are all open), the load capacitance C_{L} can be represented by the following equation.

C_{L}=(C₁₀*C₂₀)/(C₁₀+C₂₀) equation (3)

The load capacitance C_{L} can be adjusted by selectively activating the switches 131-134 and 141-144. In general, the load capacitance C_{L} increases as additional switches are activated (i.e., as additional capacitors are connected to terminals 151 and 152). Increasing the load capacitance C_{L} causes the parallel resonant frequency of oscillation fp to be reduced, as indicated by equation (2).

Although crystal oscillator circuit 100 allows the parallel resonant frequency of oscillation fp to be adjusted, the programmable load capacitors 111-114 and 121-124 require a relatively large layout area on an integrated circuit chip. It would therefore be desirable to have an improved crystal oscillator circuit, which is capable of parallel resonant frequency adjustment, but does not require an excessive layout area.

### SUMMARY

Accordingly, the present invention provides a crystal oscillator circuit having a parallel resonant frequency that is adjustable by switching trim capacitors in parallel with a crystal.

The present invention will be more fully understood in view of the following description and drawings.

### BRIEF DESCRIPTION OF THE DRAWINGS

FIG. 1 is a circuit diagram of a conventional crystal oscillator circuit having an adjustable frequency.

FIG. 2 is a circuit diagram of a crystal oscillator circuit having an adjustable frequency in accordance with one embodiment of the present invention.

FIG. 3 is a circuit diagram of a crystal oscillator circuit having an adjustable frequency in accordance with one variation of the present invention.

### DETAILED DESCRIPTION

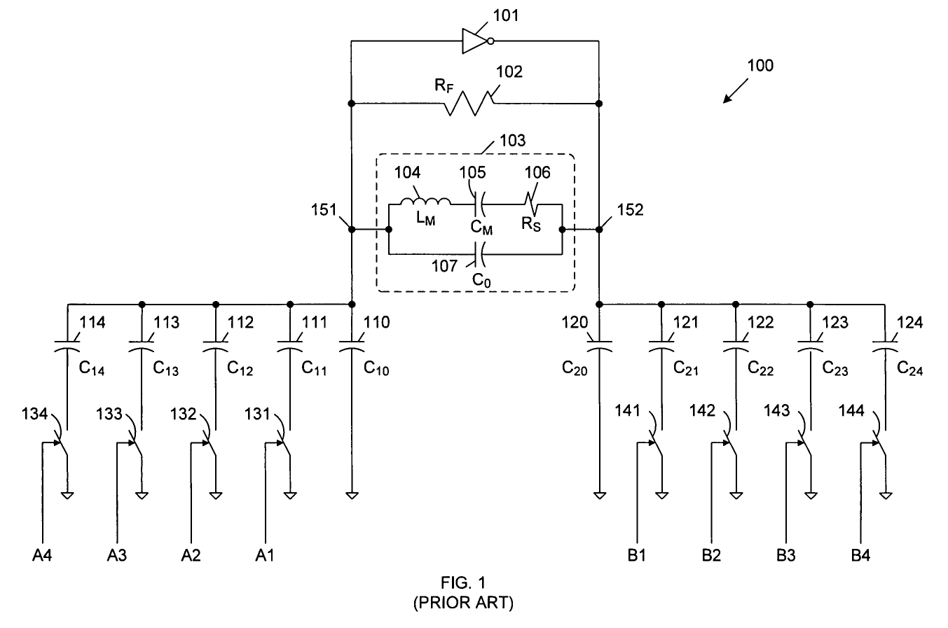

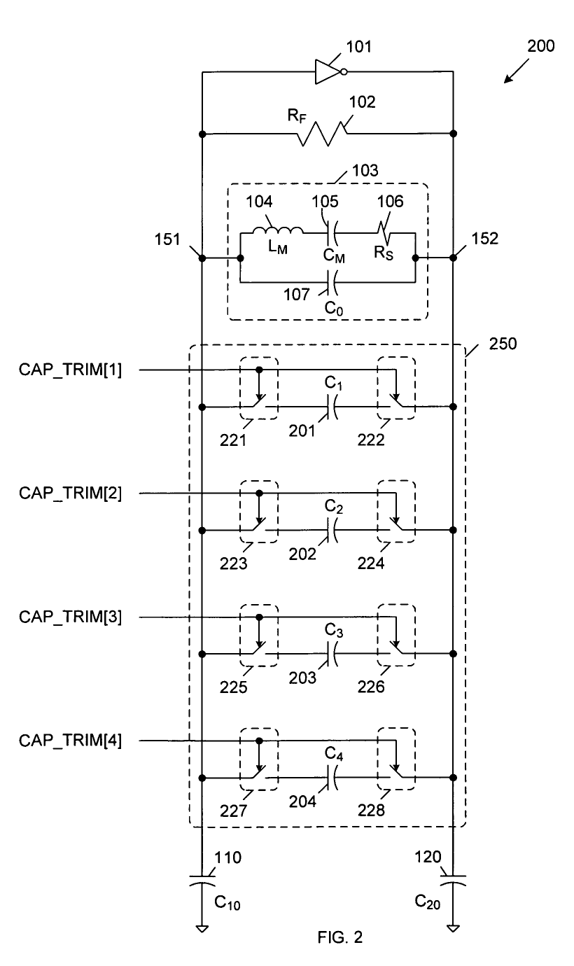

FIG. 2 is a circuit diagram of a crystal oscillator circuit 200 having an adjustable frequency in accordance with one embodiment of the present invention. Crystal oscillator circuit 200 includes inverting amplifier 101, resistor 102, crystal 103, fixed load capacitors 110 and 120, and terminals 151-152, which are described above in connection with FIG. 1. In addition, crystal oscillator circuit 200 includes parallel capacitive trim circuit 250, which is connected in parallel between terminals 151 and 152. Capacitive trim circuit 250 includes trim capacitors 201-204 and switches 221-228. A pair of switches couples each of the trim capacitors 201-204 between terminals 151 and 152. Thus, switch pairs 221-222, 223-224, 225-226 and 227-228 are configured to couple trim capacitors 201, 202, 203 and 204, respectively, between terminals 151 and 152. Each switch pair is controlled by a corresponding capacitor trim signal. For example, the switch pair 221-222 are controlled by the capacitor trim signal CAP_TRIM[1]. When the capacitor trim signal has a first logic state (e.g., a logic ‘0’ value), both switches of the corresponding switch pair are turned off (non-conductive), thereby disconnecting the corresponding trim capacitor from terminals 151 and 152. Conversely, when the capacitor trim signal has a second logic state (e.g., a logic ‘1’ value), both switches of the corresponding switch pair are turned on (i.e., conductive), thereby connecting the corresponding trim capacitor between terminals 151 and 152.

In one embodiment, more than one of the capacitor trim signals can be simultaneously activated to the second logic state, such that more than one of the trim capacitors can be simultaneously connected between terminals 151 and 152. In an alternate embodiment, the four capacitor trim signals CAP_TRIM[1:4] are generated by decoding a 2-bit control signal provided on a pair of pins of an integrated circuit chip. In this embodiment, only one of the capacitor trim signals CAP_TRIM[1:4] can be activated at any given time. Although the illustrated embodiments only implement four trim capacitors and the associated switch pairs, it is understood that other numbers of trim capacitors/switch pairs can be used in other embodiments. Trim capacitors 201, 202, 203 and 204 have capacitances C1, C2, C3 and C4, respectively. In one embodiment, capacitances C1-C4 are binary weighted, thereby enabling trimming from a minimum frequency to a maximum frequency with a predefined step. In alternate embodiments, capacitances C1-C4 can have other weightings.

The parallel resonant frequency of oscillation (fp) of crystal oscillator circuit 200 can be represented by equation (4) below, wherein C_{L} is the capacitance introduced by load capacitors 110 and 120, and C_{P} is the capacitance of the trim capacitor(s) connected between terminals 151 and 152.

$$fp = fs * [ 1 + \frac{{C}_{M}}{2 * ( {C}_{0} + {C}_{P} + {C}_{L} )} ] \qquad equation ( 4 )$$

Note that connecting a trim capacitor in parallel with crystal 103 effectively adds the capacitance of the trim capacitor to the capacitance C₀ of the crystal 103. The trim capacitance C_{P} can be adjusted by selectively activating the switches 221-228. In general, the trim capacitance C_{P} increases as additional switches are activated (i.e., as additional capacitors are connected to terminals 151 and 152), or as larger trim capacitors are connected between terminals 151 and 152. Increasing the trim capacitance C_{P} causes the parallel resonant frequency of oscillation fp to be reduced, as indicated by equation (4).

In order for the trim capacitors 201-204 of crystal oscillator circuit 200 to produces the same frequency adjustments as the programmable load capacitors 121-124 and 121-124 of crystal oscillator circuit 100, the capacitances C1-C4 of trim capacitors 201-204 should have the following relationships with respect to the capacitances C11-C14 and C21-C24 of programmable load capacitors.

C1=(C11*C21)/(C11+C21) equation (5)

C2=(C12*C22)/(C12+C22) equation (6)

C3=(C13*C23)/(C13+C23) equation (7)

C4=(C14*C24)/(C14+C24) equation (8)

In general, a trim capacitor of the present invention can replace two programmable load capacitors, wherein the trim capacitor is half the size of either of the two programmable load capacitors. For example, suppose that programmable load capacitors 111 and 121 of crystal oscillator circuit 100 (FIG. 1) have capacitances C11 and C12 of 10 pf each. In the crystal oscillator circuit 200 of the present invention, these programmable load capacitors 111 and 121 can be replaced with a single trim capacitor 201 having a capacitance C1 of 5 pf. (See, equation (5)). As a result, the chip area required by capacitors used to adjust the oscillation frequency fp is significantly reduced by the present invention.

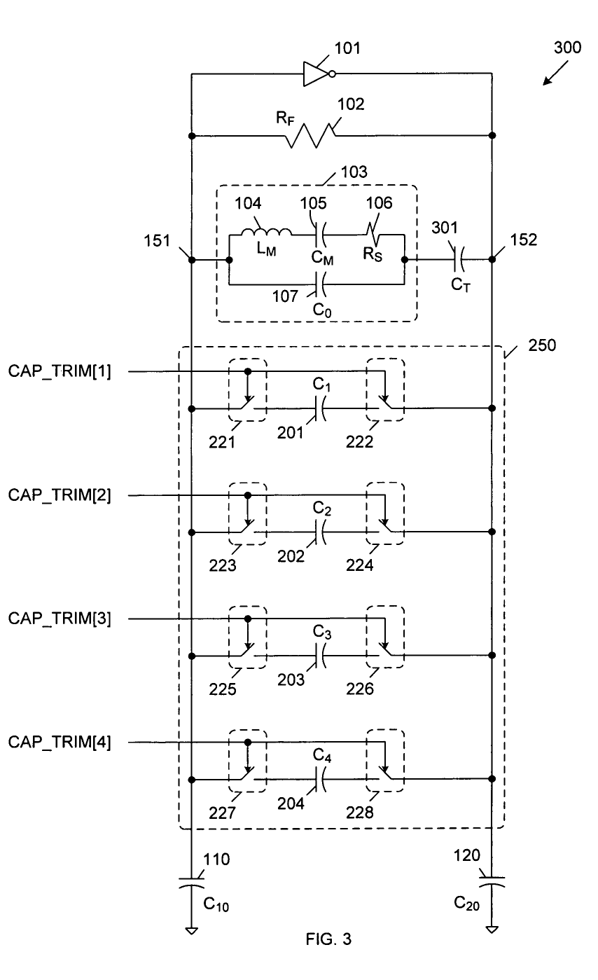

FIG. 3 is a circuit diagram of a programmable crystal oscillator circuit 300 in accordance with one variation of the present invention. Programmable crystal oscillator circuit 300 includes a series pulling capacitor 301 (having a capacitance C_{T}) in series with in series with crystal 103. Series pulling capacitor 301 increases the series resonant frequency (fs) of the oscillator circuit 300. Trim capacitors 201-204 operate in the same manner described above to adjust the parallel resonant frequency (fp) of oscillator circuit 300.

Although the present invention has been described in connection with particular embodiments, it is understood that variations in these embodiments would be apparent to one of ordinary skill in the art. Thus, the present invention is only limited by the following claims.

We claim:

1. An oscillator circuit comprising:
a first terminal;
a second terminal
an inverter, a resistor and a crystal coupled in parallel between the first and second terminals;
a first load capacitor coupled between the first terminal and a first voltage supply terminal;
a second load capacitor coupled between the second terminal and the first voltage supply terminal;
a trim circuit that includes a first switch coupled to the first terminal, a second switch coupled to the second terminal, and a first trim capacitor coupled between the first and second switches.

2. The oscillator circuit of claim 1, further comprising a first control line configured to transmit a first switch control signal to the first and second switches.

3. The oscillator circuit of claim 1, wherein the trim circuit further includes a third switch coupled to the first terminal, a fourth switch coupled to the second terminal, and a second trim capacitor coupled between the third and fourth switches.

4. The oscillator circuit of claim 3, further comprising:
a first control line configured to transmit a first switch control signal to the first and second switches; and
a second control line configured to transmit a second switch control signal to the third and fourth switches.

5. The oscillator circuit of claim 3, wherein the first trim capacitor has a different capacitance than the second trim capacitor.

6. The oscillator circuit of claim 1, further comprising a pulling capacitor connected in series with the crystal.

7. An oscillator circuit comprising:
a first terminal;
a second terminal
an inverter, a resistor and a crystal coupled in parallel between the first and second terminals;
a first load capacitor coupled between the first terminal and a first voltage supply terminal;
a second load capacitor coupled between the second terminal and the first voltage supply terminal; and
a trim circuit comprising a plurality of trim capacitors and means for selectively coupling the trim capacitors between the first terminal and the second terminal.

8. The oscillator circuit of claim 7, wherein the means for selectively coupling the trim capacitors between the first terminal and the second terminal comprise a first plurality of switches coupling the trim capacitors to the first terminal and a second plurality of switches coupling the trim capacitors to the second terminal.

9. The oscillator circuit of claim 7, wherein the trim capacitors have capacitances that are binary weighted.

10. The oscillator circuit of claim 7, wherein the trim capacitors have capacitances that are smaller/larger than capacitances of the first and second load capacitors.

11. The oscillator circuit of claim 4, further comprising a pulling capacitor connected in series with the crystal.

12. A method of adjusting the parallel resonant frequency of an oscillator circuit having a crystal, the method comprising:
closing a first switch to couple a first terminal of a first trim capacitor to a first terminal of the crystal; and
closing a second switch to couple a second terminal of the first trim capacitor to a second terminal of the crystal, whereby closing the first and second switches couples the first trim capacitor in parallel with the crystal.

13. The method of claim 12, further comprising generating a first control signal, wherein the first and second switches are closed in response to the first control signal.

14. The method of claim 12, further comprising
closing a third switch to couple a first terminal of a second trim capacitor to the first terminal of the crystal; and
closing a fourth switch to couple a second terminal of the second trim capacitor to the second terminal of the crystal, whereby closing the third and fourth switches couples the second trim capacitor in parallel with the crystal.
